(19) United States
(12) Patent Application Publication
(10) Pub. No.: US 2024/0402229 A1
(43) Pub. Date: Dec. 5, 2024

(54) ELECTRICAL ASSEMBLY

(71) Applicant: Lear Corporation, Southfield, MI (US)

(72) Inventors: Raúl Ricart, Valls (ES); Antoni Ferré Fàbregas, Valls (ES)

(73) Assignee: Lear Corporation, Southfield, MI (US)

(21) Appl. No.: 18/673,452

(22) Filed: May 24, 2024

Related U.S. Application Data
(60) Provisional application No. 63/504,765, filed on May 29, 2023.

(51) Int. Cl. G01R 27/02; B60R 16/027

(52) U.S. Cl. CPC G01R 27/02; B60R 16/027

(57) ABSTRACT

An electrical assembly comprises a track assembly; a conductor connected to the track assembly; an additional conductor connected to the track assembly; an identifier including a first terminal electrically connected to the conductor and a second terminal electrically connected to the additional conductor; and a component movably coupled with the track assembly, the component including a sensor configured to sense an electrical characteristic of the identifier.

### CROSS-REFERENCE TO RELATED APPLICATIONS

This application claims the benefit of and priority to U.S. Provisional Application 63/504,765 filed May 29, 2023, the disclosure of which is hereby incorporated by reference in its entirety as though fully set forth herein.

### TECHNICAL FIELD

The present disclosure generally relates to electrical assemblies, including electrical assemblies that include track assemblies and/or that may, for example, be used in connection with vehicles.

### BRIEF DESCRIPTION OF THE DRAWINGS

While the claims are not limited to a specific illustration, an appreciation of various aspects may be gained through a discussion of various examples. The drawings are not necessarily to scale, and certain features may be exaggerated or hidden to better illustrate and explain an innovative aspect of an example. Further, the exemplary illustrations described herein are not exhaustive or otherwise limiting, and embodiments are not restricted to the precise form and configuration shown in the drawings or disclosed in the following detailed description. Exemplary illustrations are described in detail by referring to the drawings as follows:

FIGS. 1-3 are schematic views generally illustrating embodiments of an electrical assembly according to teachings of the present disclosure.

FIGS. 4 and 5 are schematic views generally illustrating embodiments of an electrical assembly according to teachings of the present disclosure.

FIG. 6 is a schematic view generally illustrating embodiments of an identifier, conductors, and a component of an electrical assembly according to teachings of the present disclosure.

FIGS. 7 and 8 are schematic views generally illustrating embodiments of an identifier, conductors, and a component of an electrical assembly according to teachings of the present disclosure.

FIG. 9 is a schematic view generally illustrating embodiments of an identifier, conductors, and a component of an electrical assembly according to teachings of the present disclosure.

FIG. 10 is a schematic view generally illustrating embodiments of identifiers, conductors, and a component of an electrical assembly according to teachings of the present disclosure.

FIGS. 11 and 12 are schematic views generally illustrating embodiments of an identifier, conductors, and a component of an electrical assembly according to teachings of the present disclosure.

FIG. 13 is a schematic view generally illustrating embodiments identifiers, conductors, and a track wall of an electrical assembly according to teachings of the present disclosure.

FIG. 14 is a schematic view generally illustrating an embodiment of an electrical assembly according to teachings of the present disclosure.

FIG. 15 is a schematic view generally illustrating an embodiment of an electrical assembly according to teachings of the present disclosure.

FIG. 16 is a flow diagram generally illustrating an embodiment a method of operating an electrical assembly according to teachings of the present disclosure.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

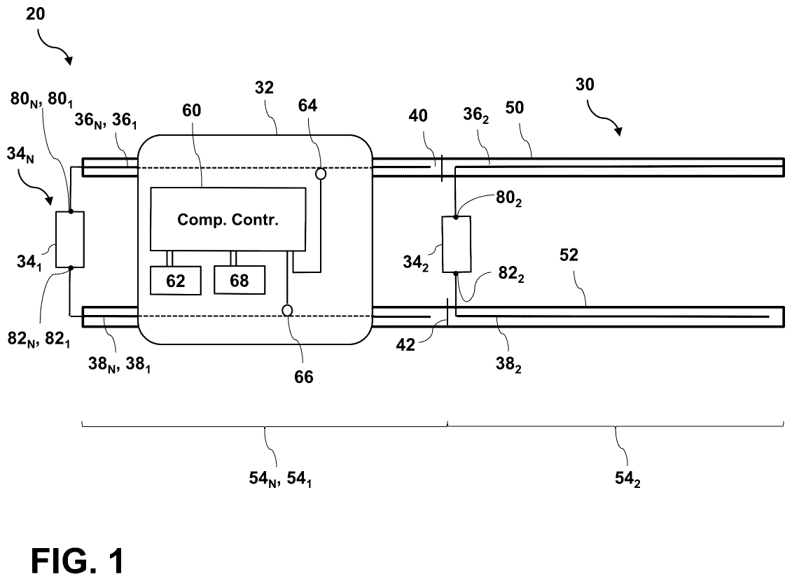

Referring to FIG. 1, an electrical assembly 20 is illustrated. The electrical assembly 20 includes a track assembly 30, a component 32, a plurality of identifiers 34_{N}, such as a first identifier 34₁ and a second identifier 34₂, and a plurality of conductors 36_{N} and additional conductors 38_{N}, such as a first conductor 36₁, a first additional conductor 38₁, a second conductor 36₂, and/or a second additional conductor 38₂. The conductors 36_{N} and/or the additional conductors 38_{N} may be separated from each other by gaps 40 and/or insulators 42. The conductors 36_{N} and the additionally conductors 38_{N} comprise one or more electrically conductive materials, such as copper, aluminum, other materials, or combinations thereof. The insulators 42 comprise materials that are electrically insulating.

The track assembly 30 includes a first track 50, a second track 52, and/or a plurality of track sections 54_{N}, such as a first track section 54₁ and a second track section 54₂. The track sections 54_{N} comprise longitudinal sections of the track assembly 30. The first track section 54₁ includes and/or is connected to the first conductor 36₁ and the first additional conductor 38₁. The additional track section(s) 54_{N} include and/or are connected to the conductors 36_{N} and additional conductors 38_{N}. For example, a second track section 54₂ is connected to the second conductor 36₂ and the second additional conductor 38₂. Optionally, the conductors 36_{N} and/or the additional conductors 38_{N} are configured as bus bars and/or are attached to and/or disposed at least partially in a wall (e.g., a vertical wall) of a track 50, 52.

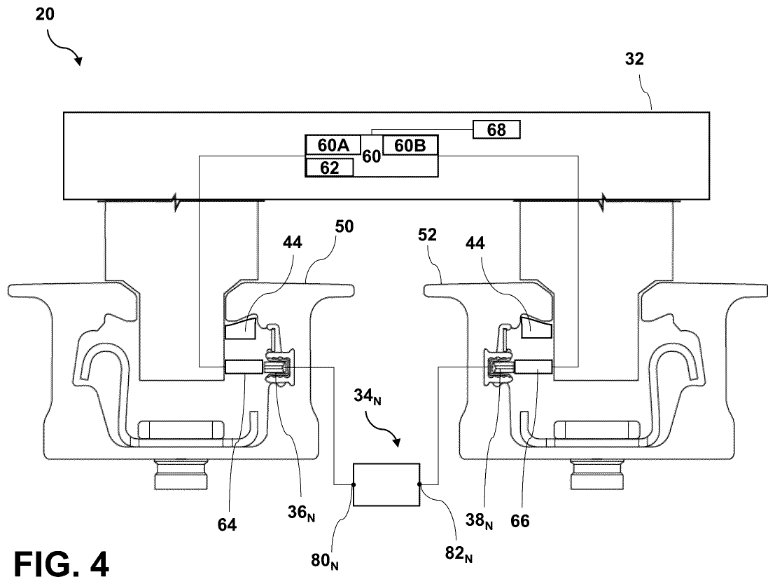

The component 32 is movably coupled with the track assembly 30. Optionally, the component 32 is configured for selective connection with, movement along and relative to (e.g., sliding), and/or removal (e.g., vertical removal) from the track assembly 30. Selective connection with the track assembly 30 includes selective electrical connection and/or selective mechanical connection. Selective mechanical connection is optionally conducted via one or more anchors 44 that can engage the track assembly 30 to restrict/prevent longitudinal movement of a component 32 along the track assembly 30 and/or restrict/prevent vertical removal of a component 32 from the track assembly 30 (see, e.g., FIG. 4).

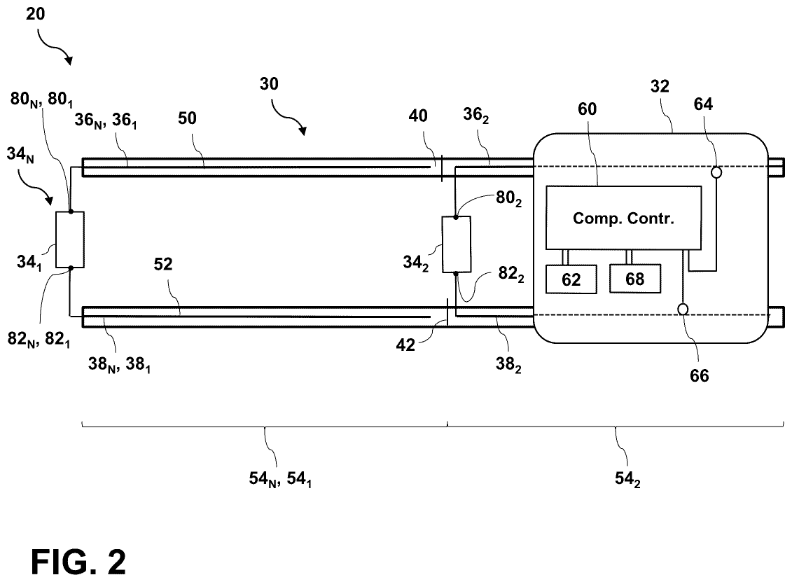

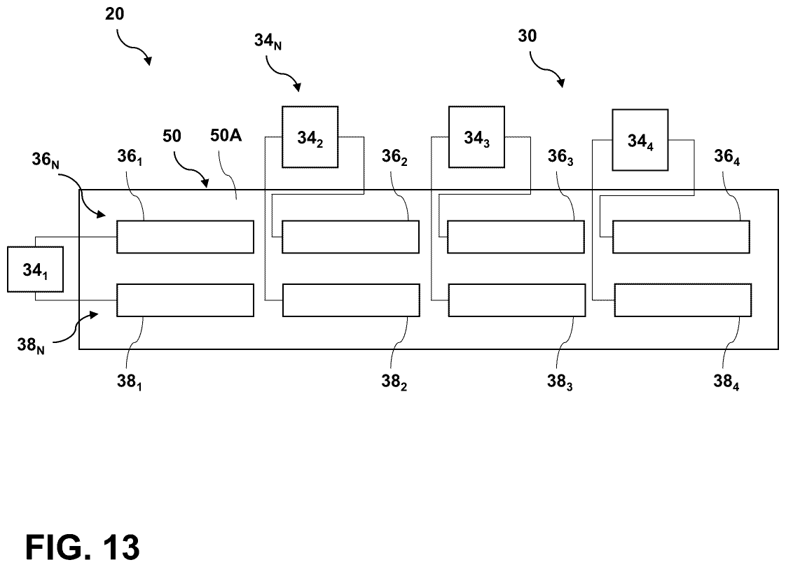

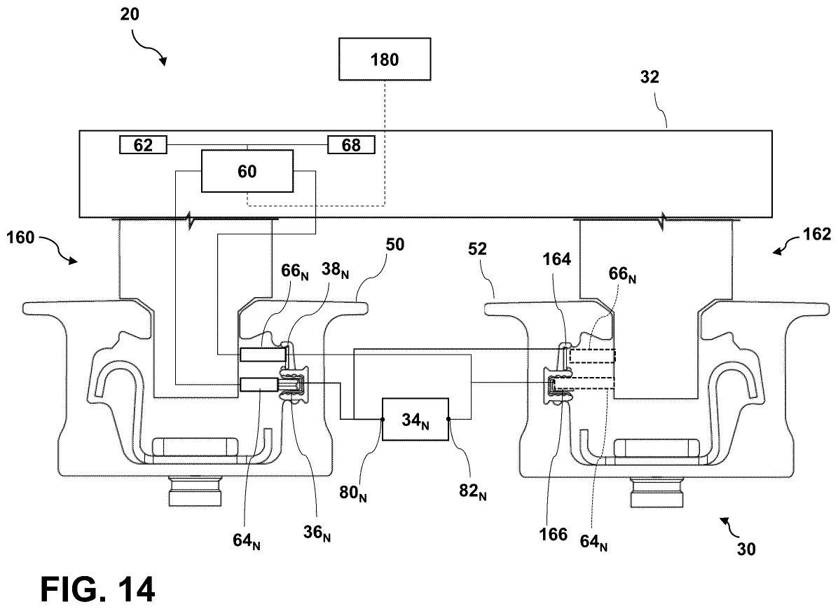

A set of conductors 36_{N} are connected to one of the first track 50 and the second track 52. A set of additional conductors 38_{N} is connected to one of the first track 50 and the second track 52. In some configurations, the set of additional conductors 38_{N} is connected to a different one of the tracks 50, 52 than the first conductor 36_{N} (see, e.g., FIGS. 1-5). In other configurations, the set of additional conductors 38_{N} is connected to the same one of the tracks 50, 52 as the first conductor 36_{N} (see, e.g., FIGS. 13 and 14).

The component 32 includes a component controller 60, a sensor 62, a first contact 64 (e.g., an electrical contact), a second contact 66 (e.g., an electrical contact), and/or a safety device 68. Optionally, the component 32 is configured as a vehicle component, such as a seat or a console, among other configurations. The component controller 60 is connected to provide signals to and/or receive signals from the sensor 62, the first contact 64, the second contact 66, and/or the safety device 68. The safety device 68 can include one or more airbags, pretensioners, pyrotechnic devices, occupancy sensors, seatbelt sensors, and/or other elements.

The sensor 62 is connected to the first contact 64 and the second contact 66 and is configured to sense one or more electrical characteristics (e.g., impedance, resistance, voltage, current, among others) associated with the contacts 64, 66 and/or elements electrically connected to the contacts 64, 66. Elements electrically connected to the contacts 64, 66 can include the conductors 36_{N}, 38_{N}, and/or elements connected to the conductors 36_{N}, 38_{N}, such as the identifier 34_{N}. For example, the sensor 62 may be configured to sense an impedance of an identifier 34_{N}, a conductor 36_{N}, and/or an additional conductor 38_{N}. Optionally, some or all of the sensor 62 is integrated into the component controller 60 (see, e.g., FIGS. 4 and 6-9).

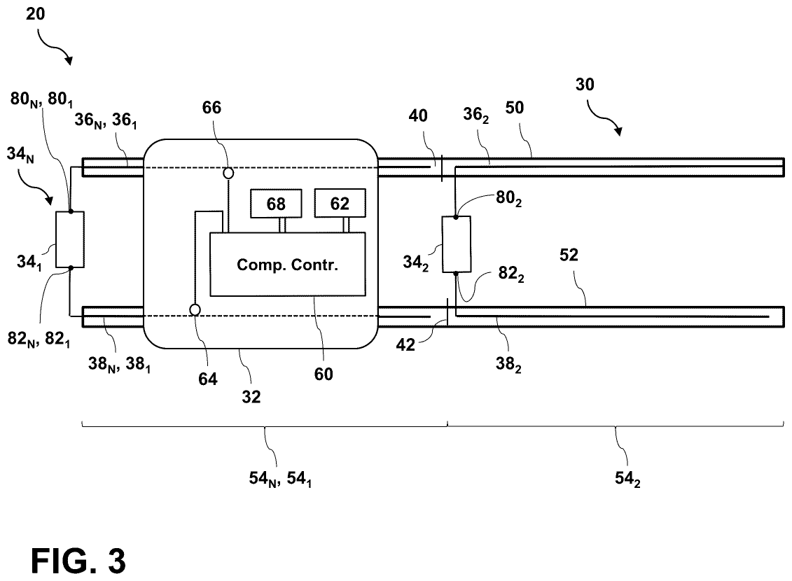

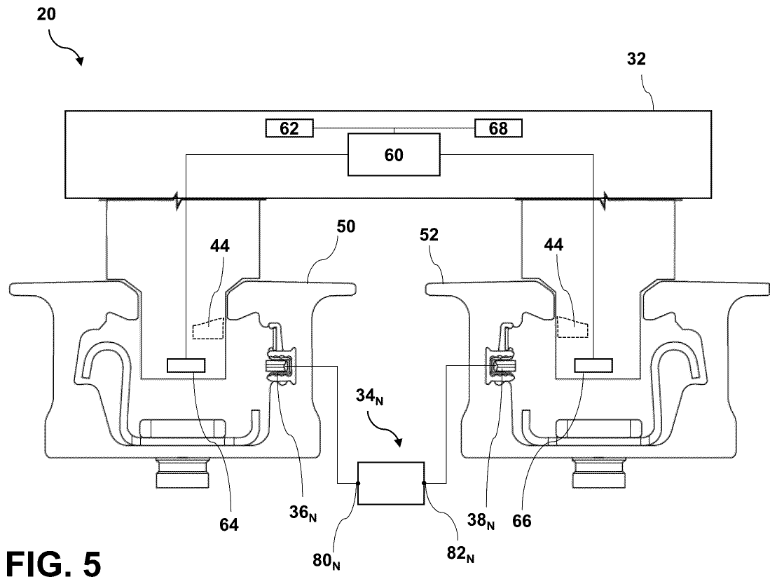

The electrical contacts 64, 66 electrically connect with the first conductor 36_{N} or the second conductor 38_{N} when the component is connected with the track assembly 30. In a first orientation of the component 32 disposed in the first section 54₁ and with conductors 36_{N}, 38_{N} connected to the tracks 50, 52, respectively (see, e.g., FIG. 1), the first electrical contact 64 is electrically connected with the first conductor 36₁, and the second electrical contact 66 is electrically connected with the first additional conductor 38₁. In a second orientation of the component 32 disposed in the first section 54₁ and with conductors 36_{N}, 38_{N} connected to the tracks 50, 52, respectively (see, e.g., FIG. 3), the first electrical contact 64 is electrically connected with the second conductor 38_{N}, and the second electrical contact 66 is electrically connected with the first conductor 36_{N}. Optionally, the contacts 64, 66 can move (e.g., rotate, tilt, translate, etc.) between an engaged position in which the contacts 64, 66 are in contact with and electrically connected to the conductors 36_{N}, 38_{N} (see, e.g., FIG. 4), and a disengaged position in which the contacts 64, 66 are not in contact with or electrically connected to the conductors 36_{N}, 38_{N} (see, e.g., FIG. 5), such as to facilitate removal (e.g., vertical removal) of the component 32 from the track assembly 30.

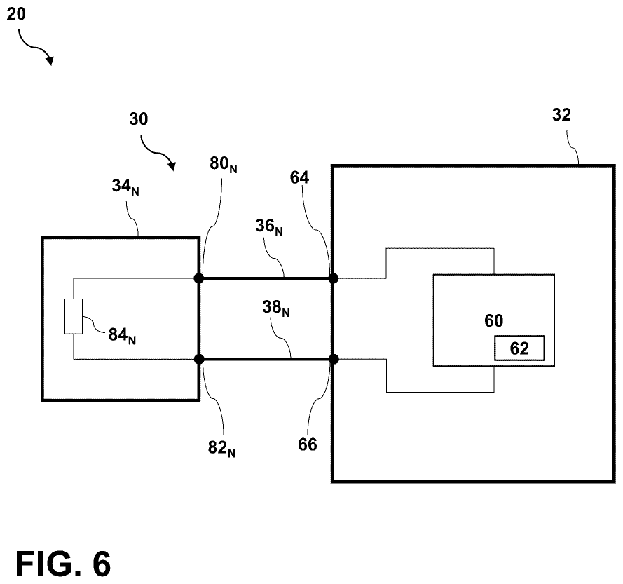

An identifier 34_{N} includes a first terminal 80_{N}, a second terminal 82_{N}, and one or more electrical devices 84_{N}. For example, first and second identifiers 34₁, 34₂ include first terminals 80₁, 80₂, second terminals 82₁, 82₂, and one or more electrical devices 84₁, 84₂. The first terminal 80_{N} is electrically connected to a first conductor 36_{N}. The second terminal 82_{N} is electrically connected to a second conductor 38_{N}. When a component 32 is electrically connected with the track assembly 30, the component controller 60 and/or the sensor 62 is electrically connected to an identifier 34_{N}. The one or more electrical devices 84_{N} can include resistors, diodes, capacitors, controllers, amplifiers, and/or other devices. In some configurations, the one or more electrical devices 84_{N} includes at least one electrical device having an impedance that can be sensed by the sensor 62. For example, as generally illustrated in FIG. 6, the one or more electrical devices 84_{N} can include a resistor 86_{N} connected to the first terminal 80_{N} and the second terminal 82_{N}. The resistor 86_{N} may have a resistance/impedance that is unique relative to electrical devices 84_{N} of other identifiers 34_{N}. Additionally or alternatively, in some configurations, the one or more electrical devices 84_{N} include a capacitor having a least one of a capacitance, a charging time, or a discharging time that can be sensed by the sensor 62 and/or that is unique relative to the electrical devices 84_{N} of other identifiers 34_{N}.

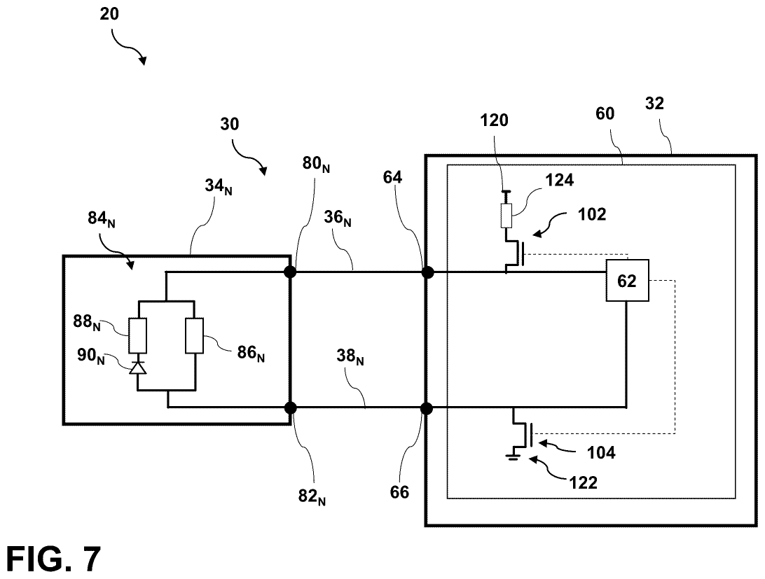

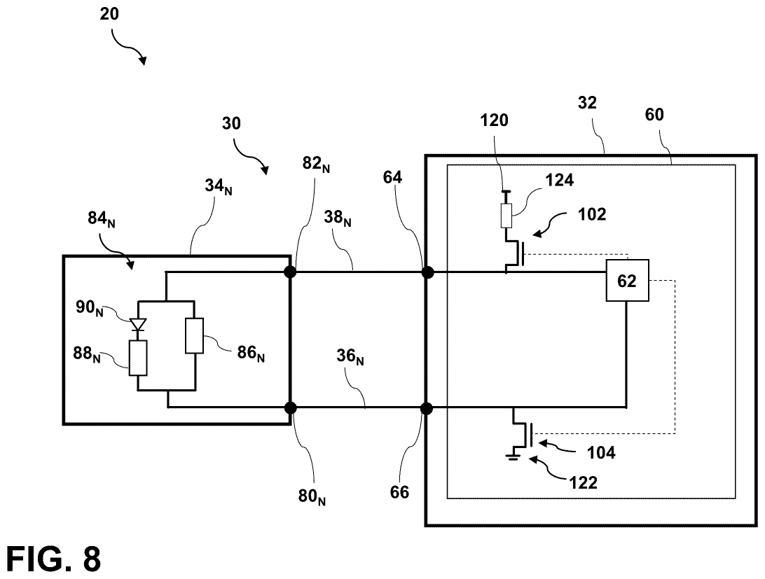

Additionally or alternatively, as generally illustrated in FIGS. 7 and 8, the one or more electrical devices 84_{N} can include a second resistor 88_{N} connected in series with a diode 90_{N}, and the second resistor 88_{N} and the diode 90_{N} can be connected in parallel with the first resistor 86_{N}. With the component 32 connected in the first orientation with the first contact 64 connected to a first conductor 38_{N} (see, e.g., FIG. 7), the sensor 62 senses the combined impedance of the two resistors 86_{N}, 88_{N} in parallel, and with the component 32 connected in a second orientation with the first contact 64 connected to a second conductor 38_{N} (see, e.g., FIG. 8), the sensor 62 senses the impedance of the first resistor 86_{N}, and the diode 90_{N} blocks the second resistor 88_{N} (see, e.g., FIG. 8).

Referring to the examples of FIGS. 7 and 8, the component controller 60 and/or the sensor 62 are configured to sense an electrical characteristic (e.g., an impedance) of the identifier 34_{N} with a first polarity and/or a second polarity. For example, the component controller 60 and/or the sensor 62 include a first switch 102 and a second switch 104. The first switch 102 is electrically connected with a voltage source 120 and the first electrical contact 64. The second switch 104 is electrically connected with the second electrical contact 66 and an electrical ground 122. A resistor 124 may be connected between the first switch 102 and the voltage source 120.

The component controller 60 is connected to control operation of the switches 102, 104. For example, if the component controller 60 closes the first switch 102 and the second switch 104 while the component 32 is in the first orientation (e.g., with the first contact 64 connected to the first conductor 36_{N} and the second contact 66 connected to the second conductor 38_{N}), a voltage from the voltage source 120 may be applied with the first polarity to the identifier 34_{N}. In the illustrated example, the diode 90_{N} blocks current flow with the first polarity, so current does not flow through the second resistor 88_{N}, and the impedance of the identifier 34_{N} sensed by the sensor 62 (e.g., a first sensed impedance) is the impedance of the first resistor 86_{N}. If the component 32 is instead in the second orientation (e.g., with the first contact 64 connected to the second conductor 38_{N} and the second contact 66 connected to the first conductor 36_{N}) when the component controller 60 closes the first switch 102 and the second switch 104, a voltage from the voltage source 120 may be applied with a second polarity (e.g., opposite the first polarity) to the identifier 34_{N}. In the illustrated example, the diode 90_{N} does not block current flow with the second polarity, so current flows through the first resistor 86_{N} and the second resistor 88_{N}, and the impedance of the identifier 34_{N} sensed by the sensor 62 (e.g., a second sensed impedance) is the impedance of the first resistor 86_{N} and the second resistor 88_{N} in parallel (e.g., the inverse of the sum of the inverses of their respective impedances). A component controller 60 can include a component processor 60A and/or a component memory 60B (see, e.g., FIG. 4).

Each identifier 34_{N} can include a unique first and second impedance, such as by including first and second resistors 86_{N}, 88_{N} having unique impedance. The first and second impedance of each identifier 34_{N} may be stored in and/or accessible by the component controller 60 such that when the sensor 62 senses a particular impedance, the component controller 60 can match the sensed impedance with a corresponding section 54_{N} and orientation.

The component controller 60 may determine which section 54_{N} (FIG. 3) of the track assembly 30 that the component 32 is disposed in and/or the orientation of the component 32 relative to the track assembly 30 (e.g., forward, rearward) according, at least in part, to the output of the sensor 62, which may correspond to the sensed electrical characteristic (e.g., impedance) of the identifier 34_{N}. For example, if the component controller 60 closes the first and second switches 102, 104 and the sensor 62 senses the first impedance of a first identifier 34_{N}, the component controller 60 may determine that the component 32 is in the first section 54₁ and in the first orientation. If the sensor 62 instead senses the second impedance of the first identifier 34_{N}, the component controller 60 may determine that the component 32 is in the first section 54₁ and in the second orientation.

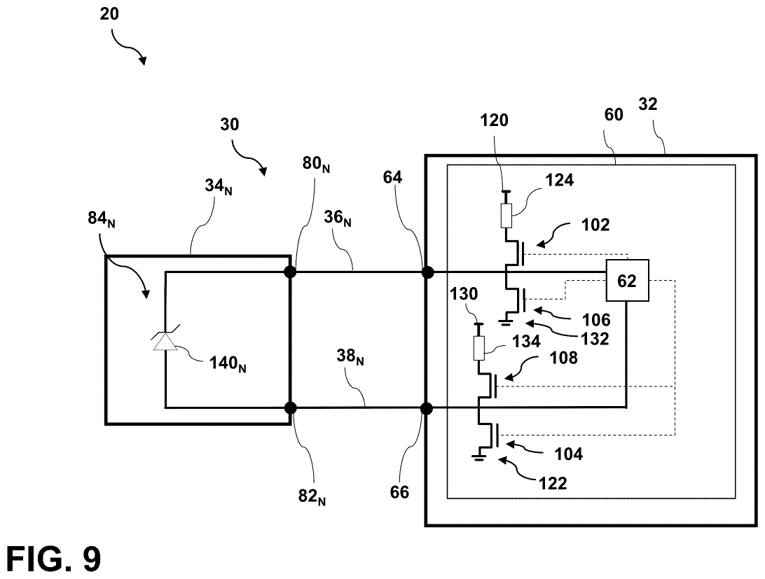

Referring to FIG. 9, a component 32 is illustrated with a component controller 60 and/or a sensor 62 that are configured to sense an impedance of the identifier 34_{N} with a first polarity and a second polarity. For example, the component controller 60 and/or the sensor 62 include a first switch 102, a second switch 104, a third switch 106, and a fourth switch 108. The first switch 102 is electrically connected with a voltage source 120 and the first electrical contact 64. The second switch 104 is electrically connected with the second electrical contact 66 and an electrical ground 122. The third switch 106 is electrically connected with the first electrical contact 64 and an electrical ground 132, which may be same as or connected to the electrical ground 122. The fourth switch 108 is electrically connected with the second electrical contact 66 and a voltage source 130, which may be the same as or connected to the voltage source 120. A resistor 134 may be connected between the fourth switch 108 and the second electrical contact 66. The electrical device 84_{N} of an identifier 34_{N} may include a Zener diode 140_{N}.

The component controller 60 is connected to control operation of the switches 102-108. For example, if the component controller 60 closes the first switch 102 and the second switch 104 while the component 32 is in the first orientation (e.g., with the first contact 64 connected to the first conductor 36_{N} and the second contact 66 connected to the second conductor 38_{N}), a voltage from the voltage source 120 may be applied with a first polarity to the identifier 34_{N}. In the illustrated example, the Zener diode 140_{N} is reverse-biased with the first polarity, so if the voltage provided by the voltage source 120 is above the Zener voltage of the Zener diode 140_{N}, the impedance of the identifier 34_{N} sensed by the sensor 62 (e.g., a first sensed impedance) corresponds to the Zener voltage of the Zener diode 140_{N}.

If the component controller 60 instead closes the third switch 106 and the fourth switch 108 while the component 32 is in the first orientation, a voltage from the voltage source 130 may be applied with a second polarity (e.g., opposite the first polarity) to the identifier 34_{N}. In the illustrated example, the Zener diode 140_{N} is forward-biased with the second polarity, so the impedance of the identifier 34_{N} sensed by the sensor 62 (e.g., a second sensed impedance) may correspond to the voltage drop of the Zener diode 140_{N}, which may, for example, be about 0.7 V for a silicon Zener diode.

Each identifier 34_{N} can include a unique first impedance. For example, a Zener diode 140_{N} of each identifier 34_{N} can include a different Zener voltage. The second impedance of the identifiers 34_{N} may be substantially the same, so the component controller 60 may operate the switches 102-108 to apply the opposite polarity to an identifier 34_{N} if the original polarity resulted in the sensor 62 sensing the second impedance. The first impedance of each identifier 34_{N} may be stored in and/or accessible by the component controller 60 such that when the sensor 62 senses a particular first impedance, the component controller 60 can match the sensed first impedance with a corresponding section 54_{N}.

The component controller 60 may determine which section 54_{N} (FIG. 3) of the track assembly 30 that the component 32 is disposed in and/or the orientation of the component 32 relative to the track assembly 30 (e.g., forward, rearward) according, at least in part, to the output of the sensor 62, which may correspond to the sensed impedance of the identifier 34_{N}. For example, if the component controller 60 closes the first and second switches 102, 104 and the sensor 62 senses a first impedance associated with the Zener diode 140_{N} of a first identifier 34_{N}, the component controller 60 may determine that the component 32 is in the first section 54₁ and in the first orientation. If the sensor 62 instead senses the second impedance of the Zener diode 140_{N} of the first identifier 34_{N}, the component controller 60 may determine that the component 32 is in the second orientation. If the sensor 62 senses the second impedance, the component controller 60 may apply the opposite polarity to obtain the first impedance of the identifier 34_{N} to determine which section 54_{N} the component 32 is disposed in.

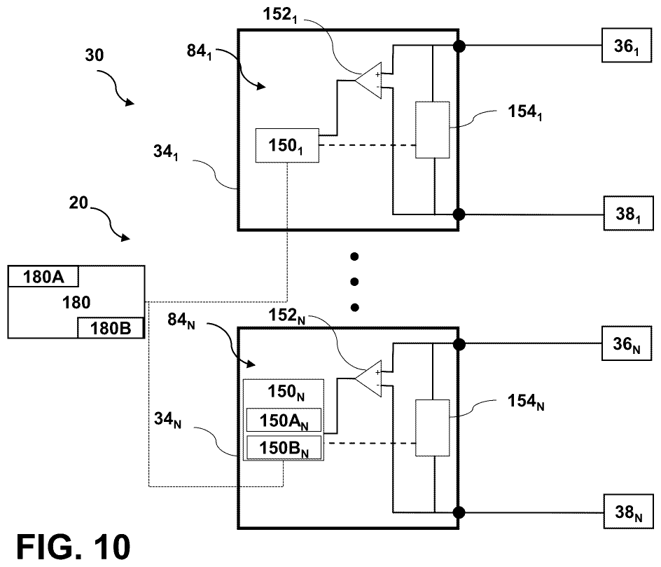

Referring to FIG. 10, an identifier 34_{N} optionally includes an active configuration. For example, an identifier 34_{N} can include an identifier controller 150_{N}, a comparator 152_{N}, and/or a variable impedance device 154_{N} (e.g., a digital potentiometer). For example, a first identifier 34₁ includes an identifier controller 150₁, a comparator 152₁, and/or a variable impedance device 154₁. The comparator 152_{N} is connected to the first terminal 80_{N} and the second terminal 82_{N}, and provides an output to the identifier controller 150_{N} corresponding to the voltage provided by the component controller 60 and/or the sensor 62. If the output from the comparator 152_{N} positive, such as when the first contact 64 is connected with the first conductor 36_{N}, the identifier controller 150_{N} can control the variable impedance device 154_{N} to provide an impedance (e.g., a first impedance) corresponding to the component 32 being disposed in the first section 54₁ and having the first orientation. If the output from the comparator 152_{N} is negative, such as when the second contact 66 is connected with the first conductor 36_{N}, the identifier controller 150_{N} can control the variable impedance device 154_{N} to provide a different impedance (e.g., a second impedance) corresponding to the component 32 being disposed in the first section 54₁ and having the second orientation. An identifier controller 150_{N} may include a processor 150A_{N} and/or a memory 150B_{N}.

One or more additional identifiers 34_{N} can be connected to respective additional conductors 36_{N}, 38_{N} of additional sections 54_{N} of the track assembly 30. For example, each additional identifier 34_{N} can include an identifier controller 150_{N} that controls a variable impedance device 154_{N}, such as according to the output of a comparator 152_{N}, to provide a first impedance and a second impedance that are different from each other identifier 34_{N}.

Optionally, the component controller 60 can communicate with an identifier controller 150_{N} to obtain information other than component section and orientation information. For example, if the component controller 60 provides a first component electrical characteristic, such as voltage (e.g., 5 V), the identifier controller 150_{N} may control the variable impedance device 154_{N} to provide the first or second impedance corresponding to the component section and orientation, and if the component controller 60 provides a second electrical characteristic, such as a voltage (e.g., 3 V), the identifier controller 150_{N} may control the variable impedance device 154_{N} to provide a third impedance corresponding to a different parameter, such as, for example and without limitation, battery voltage, battery charge level, vehicle speed, and/or other parameters. Optionally, some or all of the identifier controllers 150_{N} are partially or completely included with another controller 180, such as a vehicle controller for vehicle applications. Additionally or alternatively, the identifier controllers 150_{N} are in communication with the controller 180. In some configurations, each component 32 may provide a unique electrical characteristic (e.g., voltage, impedance, etc.) to an identifier 34. The identifier controller 150_{N} and/or the controller 180 may utilize the electrical characteristic provided by a component 32 to identify the component 32. For example and without limitation, a component 32 may provide a unique voltage and/or a unique impedance that can be sensed via an identifier controller 150_{N} and/or a controller 180. The controller 180 may include a processor 180A and/or a memory 180B.

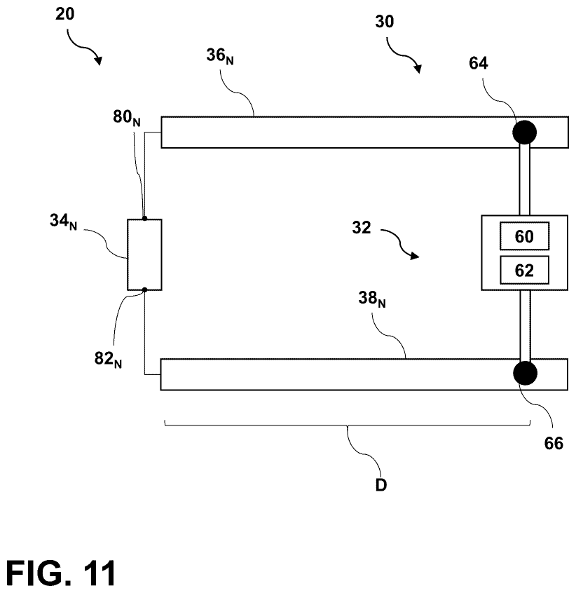

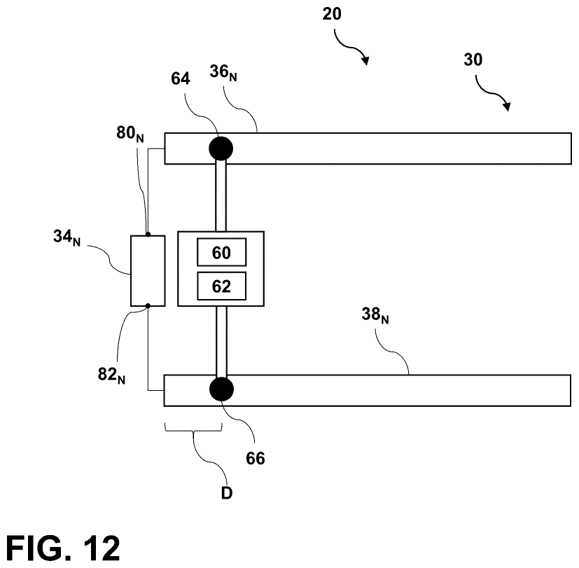

Referring to FIGS. 11 and 12, optionally, the component controller 60 and/or the sensor 62 determine a position of a component 32 within a section 54_{N} according, at least in part to a resistivity of the conductors 36_{N}, 38_{N}. The resistivity includes a resistance per unit length, so the impedance sensed by sensor 62 when sensing the impedance of an identifier 34_{N} will vary depending on the distance D of the component 32 from the connection of the identifier 34_{N} to the conductors 36_{N}, 38_{N}. For example, the impedance sensed by the sensor 62 may correspond to the sum of (i) the impedance of the identifier 34_{N} and (ii) a product of the combined resistivity of the conductors 36_{N}, 38_{N} and the distance D from the identifier connection. The component controller 60 may utilize that relationship to determine the position of the component 32 within the section 54_{N} (e.g., the distance D from the connection of the identifier 34_{N} to the conductors 36_{N}, 38_{N}). For example larger sensed impedances can indicate a greater distance D (e.g., FIG. 11) and smaller sensed impedances can indicate a shorter distance D (e.g., FIG. 12).

With some configurations, a total range of impedance for each section 54_{N}, which may include the sum of impedance of the identifier 34_{N} and a maximum impedance of the conductors 36_{N}, 38_{N} (e.g., when the component 32 is farthest from the identifier connection), may be unique for each section 54_{N}. With such configurations, the component controller 60 may initially determine which section 54_{N} the component 32 is disposed in according to the sensed impedance. The component controller 60 may then determine the position of the component 32 in the section 54_{N} by subtracting the impedance of the identifier 34_{N} of the determined section 54_{N}, which may be stored in and/or accessible by the component controller 60, and dividing that difference by the combined resistivity of the conductors 36_{N}, 38_{N} to obtain the distance D. In some configurations, the identifier 34_{N} is to connected to the same ends (e.g., forward ends or rearward ends) of the conductors 36_{N}, 38_{N}. Optionally, the conductors 36_{N}, 38_{N} include a material with a resistivity greater than copper, such as stamped steel, among other possible materials.

Referring to FIGS. 13 and 14, the conductors 36_{N}, 38_{N} are optionally connected to the same track, such as a first track 50, and/or to the same wall 50A of a first track 50. For example, conductors 36₁₋₄ and additional conductors 38₁₋₄ can be connected to the same wall 50A, and respective identifiers 34₁₋₄ can be connected thereto. If the component 32 includes a dual track configuration, a first side 160 of the component 32 may include both contacts 64, 66, and a second side 162 of the component 32 may not include either of the contacts 64, 66. Optionally, such as generally illustrated in FIG. 14, a second track 52 includes third and fourth conductors 164, 166 disposed such that when the component 32 is connected with the tracks 50, 52 in a second orientation (e.g., with the first side 160 engaged with the second track 52, and the second side 162 engaged with the track 50), the contacts 64, 66 may contact and electrically connect with the third and fourth conductors 164, 166 (see dashed lines in FIG. 14). The third and fourth conductors 164, 166 may be electrically connected to the identifier 34_{N} in an opposite configuration from the conductors 36_{N}, 38_{N} such that, if the first and contacts 64, 66 are electrically connected to the first and second terminals 80_{N}, 82_{N}, respectively, when the component 32 is in the first orientation, and the first and contacts 64, 66 are electrically connected to the second and first terminals 82_{N}, 80_{N}, respectively, when the component 32 is in the second orientation.

In some configurations, the conductors 36_{N}, 38_{N} may take the form of the tracks 50, 52 and be included with the track assembly 30. In such configurations, the identifiers 34_{N} may be connected directly to the tracks 50, 52, the sections 54_{N} of the track assembly 30 may be electrically isolated from each other, and/or the track assembly 30 may be electrically isolated from the mounting surface and/or electrical ground.

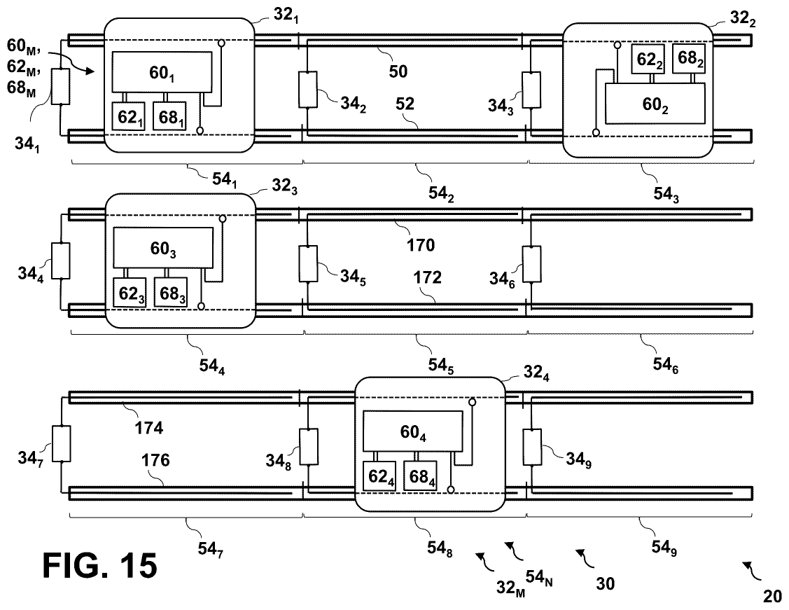

While various examples have been illustrated and described in connection with a first track 50 and a second track 52, a track assembly 30 may include other numbers of tracks with additional track sections 54_{N} (see, e.g., FIG. 15). For example and without limitation, a track assembly 30 may include a first track 50, a second track 52, a third track 170, a fourth track 172, a fifth track 174, and/or a sixth track 176, each with respective track sections 54_{N} (e.g., sections 54₁₋₉), conductors (e.g., conductors 36₁₋₉, 38₁₋₉), and/or identifiers (e.g., identifiers 34₁₋₉). A component controller 60_{M} (e.g., component controllers 60₁₋₄) may be configured to determine which section of the plurality of sections 54_{N} (e.g., sections 54₁₋₉) a component 32 is connected to and/or an orientation of the component 32, such as according to an electrical characteristic (e.g., an impedance) of the respective identifier 34_{N} sensed via the sensors 62_{M} (e.g., sensors 62₁₋₄). In some configurations, the tracks 50, 52, 170-176 are parallel with each other.

A plurality of components 32_{N} (e.g., components 32₁₋₄) can be connected to the same track assembly 30. The component controllers 60_{M} of the components 32_{M} may be configured to determine which section of the plurality of sections 54_{N} (e.g., sections 54₁₋₉) a component 32_{N} is connected to and/or an orientation of the component 32_{M}, such as according to an electrical characteristic (e.g., an impedance) of the respective identifier 34_{N} sensed via a sensor 62_{M}. The components 32_{N} may include respective safety devices 68_{M}.

In some configurations, the component controllers 60_{M} are configured to compensate for the presence (e.g., impedance, capacitance, charging time, discharging time, etc.) of additional components 32_{M} connected to the same section 54₂. For example and without limitation, an expected impedance and/or capacitance of a component 32_{M} may be stored in and/or accessible by the component controllers 60_{M}, and if a sensed impedance and/or capacitance is above a threshold, the component controller 60_{M} may subtract a component impedance and/or capacitance from the sensed value.

Additionally or alternatively, the length of the sections 54_{N} optionally corresponds to the size of the components 32_{N} such that not more than one component 32_{M} is electrically connected to the same section 54_{N} at a time.

With embodiments, an electrical assembly 20 may be configured such that the position and/or orientation of a component 32 relative to a track assembly 30 can be determined, such as via a component controller 60. The component controller 60 may utilize the position and/or orientation information to control one or more functions of the component 32 (e.g., movement), control actuation of one or more safety devices 68, and/or provide the information to another controller (e.g., controller 180). For example, certain safety devices 68 may or may not be actuated, and/or a sequencing of actuation may change, depending on the position and orientation of the component 32. In some configurations, the identifiers 34_{N} may include passive components and may not include active/powered components (see, e.g., FIGS. 6-9). In other configurations, the identifiers 34_{N} may include active components (see, e.g., FIGS. 10 and 11), or a combination thereof. The component controllers 60 may be in communication (e.g., wired and/or wireless) with another controller 180, which may, for vehicle applications, include a vehicle controller configured to control one or more systems of a vehicle (e.g., propulsion, braking, infotainment, safety, among others).

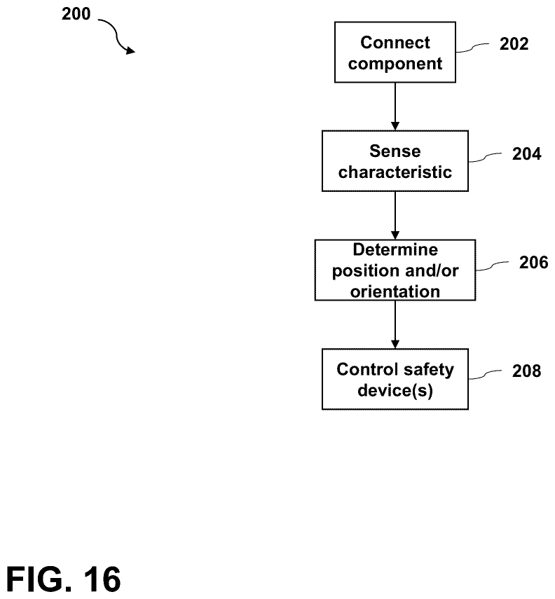

A method 200 of operating an electrical assembly 20 is illustrated in FIG. 16. The method 200 includes connecting a component 32 to a track assembly 30 (block 202). The method 200 includes sensing, via a component controller 60 and/or a sensor 62, an electrical characteristic of an identifier 34_{N} electrically connected to a pair of conductors 36_{N}, 38_{N} (block 204). The method 200 includes the component controller 60 determining a position and/or an orientation of the component 32 relative to the track assembly 30 according to an output of the sensor 62 and/or an electrical characteristic of the identifier 34_{N} (block 206). Determining the position can include determining which section of a plurality of sections 54_{N} the component 32 is connected to, such as according to the electrical characteristic of the identifier 34_{N}. Additionally or alternatively, the component controller 60 may determine the position of the component 32 within a section 54_{N} according to the electrical characteristic and/or one or more resistivities of the conductors 36_{N}, 38_{N}. Optionally, the method 200 includes a component controller 60 controlling operation of one or more safety devices 68_{N} according to the determined position and/or orientation (block 208). Component controllers 60_{M} of other components 32_{N} may conduct the method 200 at the same or a different time to determine the position and/or orientation of the other components 32_{M}.

The instant disclosure includes the following non-limiting embodiments:

An electrical assembly, comprising: a track assembly; a conductor connected to the track assembly; an additional conductor connected to the track assembly; an identifier including a first terminal electrically connected to the conductor and a second terminal electrically connected to the additional conductor; and a component movably coupled with the track assembly, the component including a sensor configured to sense an electrical characteristic of the identifier.

The electrical assembly according to any preceding embodiment, wherein the identifier includes a resistor and/or a diode.

The electrical assembly according to any preceding embodiment, wherein the conductor is connected to a first track of the track assembly; and the additional conductor is connected to a second track of the track assembly.

The electrical assembly according to any preceding embodiment, wherein the first conductor and the second conductor are connected to a first track of the track assembly.

The electrical assembly according to any preceding embodiment, further comprising one or more additional identifiers electrically connected to one or more other pairs of conductors and additional conductors connected to the track assembly.

The electrical assembly according to any preceding embodiment, wherein each pair of the one or more pairs of conductors and additional conductors includes a second conductor connected to a first track of the track assembly and a second additional conductor connected to a second track of the track assembly.

The electrical assembly according to any preceding embodiment, wherein the electrical characteristic of the identifier and electrical characteristics of each of the one or more additional identifiers are different.

The electrical assembly according to any preceding embodiment, wherein the track assembly includes a plurality of sections including a first section and one or more additional sections; the conductor and the additional conductor are connected to the first section; and the one or more pairs of other conductors and additional conductors are connected to respective sections of the one or more additional sections; the sensor is configured to sense electrical characteristics of the one or more additional identifiers; and the component includes a component controller configured to determine which section of the plurality of sections the component is connected to according to an output from the sensor.

The electrical assembly according to any preceding embodiment, wherein the component controller is configured to determine an orientation of the component according to an output from the sensor.

The electrical assembly according to any preceding embodiment, wherein the conductor, the additional conductor, and the one or more pairs of other conductors have respective resistivities; and the component controller is configured to determine a position of the component within the section according to the output of the sensor and one or more of the resistivities.

The electrical assembly according to any preceding embodiment, wherein the resistivities are equal.

The electrical assembly according to any preceding embodiment, wherein the component includes a first movable electrical contact that electrically connects the component with the first conductor, and a second movable contact that electrically connects the component with the second conductor.

The electrical assembly according to any preceding embodiment, wherein the electrical characteristic includes an impedance; and the impedance has a first value when the component is connected to the conductor and the additional conductor in a first direction, and a second value that is different from the first value when the component is connected to the conductor and the additional conductor in a second direction.

The electrical assembly according to any preceding embodiment, wherein the identifier includes a resistor and a diode connected in series.

The electrical assembly according to any preceding embodiment wherein, wherein the identifier includes a capacitor.

The electrical assembly according to any preceding embodiment, wherein the identifier includes a second resistor in parallel with the resistor and the diode.

The electrical assembly according to any preceding embodiment, wherein the identifier includes a Zener diode.

The electrical assembly according to any preceding embodiment, wherein the identifier includes an identifier controller and a variable resistor; and the identifier controller adjusts a resistance of the variable resistor according to a component electrical characteristic provided by the component to across the conductor and the additional conductor; and the electrical characteristic of the identifier includes the resistance.

The electrical assembly according to any preceding embodiment, wherein the component includes a component controller configured to control the component electrical characteristic provided by the component.

The electrical assembly according to any preceding embodiment, wherein the component includes a component controller configured to determine a position of the component relative to the track assembly according to the electrical characteristic and a resistivity of the first conductor.

The electrical assembly according to any preceding embodiment, wherein the conductor includes a first track of the track assembly; and the additional conductor includes a second track of the track assembly.

A method of operating the electrical assembly of any preceding embodiment, the method comprising connecting a component to a track assembly; sensing an electrical characteristic of an identifier of the component; determining a position of the component relative to the track assembly according to the electrical characteristic; and controlling one or more safety devices according to the determined position.

The method of any preceding embodiment, wherein the electrical characteristic includes at least one of a resistance, an impedance, a charge time, a discharge time, or a capacitance.

An electronic controller configured to operate any preceding embodiment.

An electronic controller configured to conduct the method of any preceding embodiment.

A non-transitory computer-readable storage medium having a computer program encoded thereon for implementing the method of any preceding embodiment.

In examples, a controller (e.g., a component controller 60M, an identifier controller 150x) may include an electronic controller and/or include an electronic processor, such as a programmable microprocessor and/or microcontroller. In embodiments, a controller may include, for example, an application specific integrated circuit (ASIC) and/or an embedded controller. A controller may include a central processing unit (CPU), a memory (e.g., a non-transitory computer-readable storage medium), and/or an input/output (I/O) interface. A controller may be configured to perform various functions, including those described in greater detail herein, with appropriate programming instructions and/or code embodied in software, hardware, and/or other medium. In embodiments, a controller may include a plurality of controllers. In embodiments, a controller may be connected to a display, such as a touchscreen display.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” “an embodiment,” “with some configurations,” “in some configurations,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” “an embodiment,” “with some configurations,” “in some configurations,” or the like, in places throughout the specification are not necessarily all referring to the same embodiment. Furthermore, the particular features, structures, and/or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof. The word “exemplary” is used herein to mean “serving as a non-limiting example.”

It should be understood that references to a single element are not necessarily so limited and may include one or more of such element, unless the context clearly indicates otherwise. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

“One or more” includes a function being performed by one element, a function being performed by more than one element, e.g., in a distributed fashion, several functions being performed by one element, several functions being performed by several elements, or any combination of the above. The term “at least one of” in the context of, e.g., “at least one of A, B, and C” or “at least one of A, B, or C” includes only A, only B, only C, or any combination or subset of A, B, and C, including any combination or subset of one or a plurality of A, one or a plurality of B, and one or a plurality of C.

Although the terms first, second, etc. are, in some instances, used herein to describe various elements, these elements should not be limited by these terms. These terms are only used to distinguish one element from another. For example, a first element could be termed a second element, and, similarly, a second element could be termed a first element, without departing from the scope of the various described embodiments. The first element and the second element are both elements, but they are not the same element.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. The term “and/or” as used herein refers to and encompasses any and all possible combinations of one or more of the associated listed items. Uses of “and” and “or” are to be construed broadly (e.g., to be treated as “and/or”). For example and without limitation, uses of “and” do not necessarily require all elements or features listed, and uses of “or” are inclusive unless such a construction would be illogical. The terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples.

While processes, systems, and methods may be described herein in connection with one or more steps in a particular sequence, such methods may be practiced with the steps in a different order, with certain steps performed simultaneously, with additional steps, and/or with certain described steps omitted.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

All matter contained in the above description or shown in the accompanying drawings shall be interpreted as illustrative only and not limiting. Changes in detail or structure may be made without departing from the present disclosure.

A controller, an electronic control unit (ECU), a system, and/or a processor as described herein may include a conventional processing apparatus known in the art, which may be capable of executing preprogrammed instructions stored in an associated memory, all performing in accordance with the functionality described herein. To the extent that the methods described herein are embodied in software, the resulting software can be stored in an associated memory and can also constitute means for performing such methods. Such a system or processor may further be of the type having ROM, RAM, RAM and ROM, and/or a combination of non-volatile and volatile memory so that any software may be stored and yet allow storage and processing of dynamically produced data and/or signals.

An article of manufacture in accordance with this disclosure may include a non-transitory computer-readable storage medium having a computer program encoded thereon for implementing logic and other functionality described herein. The computer program may include code to perform one or more of the methods disclosed herein. Such embodiments may be configured to execute via one or more processors, such as multiple processors that are integrated into a single system or are distributed over and connected together through a communications network, and the communications network may be wired and/or wireless. Code for implementing one or more of the features described in connection with one or more embodiments may, when executed by a processor, cause a plurality of transistors to change from a first state to a second state. A specific pattern of change (e.g., which transistors change state and which transistors do not), may be dictated, at least partially, by the logic and/or code.

What is claimed is:

1. An electrical assembly, comprising:
a track assembly;
a conductor connected to the track assembly;
an additional conductor connected to the track assembly;
an identifier including a first terminal electrically connected to the conductor and a second terminal electrically connected to the additional conductor; and
a component movably coupled with the track assembly, the component including a sensor configured to sense an electrical characteristic of the identifier.

2. The electrical assembly of claim 1, wherein the identifier includes a resistor, a capacitor, and/or a diode.

3. The electrical assembly of claim 1, wherein the conductor is connected to a first track of the track assembly; and
the additional conductor is connected to a second track of the track assembly.

4. The electrical assembly of claim 1, wherein the first conductor and the second conductor are connected to a first track of the track assembly.

5. The electrical assembly of claim 1, further comprising one or more additional identifiers electrically connected to one or more other pairs of conductors and additional conductors connected to the track assembly.

6. The electrical assembly of claim 5, wherein each pair of the one or more pairs of conductors and additional conductors includes a second conductor connected to a first track of the track assembly and a second additional conductor connected to a second track of the track assembly.

7. The electrical assembly of claim 5, wherein the electrical characteristic of the identifier and electrical characteristics of each of the one or more additional identifiers are different.

8. The electrical assembly of claim 7, wherein the track assembly includes a plurality of sections including a first section and one or more additional sections;
the conductor and the additional conductor are connected to the first section; and
the one or more pairs of other conductors and additional conductors are connected to respective sections of the one or more additional sections;
the sensor is configured to sense electrical characteristics of the one or more additional identifiers; and
the component includes a component controller configured to determine which section of the plurality of sections the component is connected to according to an output from the sensor.

9. The electrical assembly of claim 8, wherein the component controller is configured to determine an orientation of the component according to an output from the sensor.

10. The electrical assembly of claim 8, wherein the conductor, the additional conductor, and the one or more pairs of other conductors have respective resistivities; and
the component controller is configured to determine a position of the component within the section according to the output of the sensor and one or more of the resistivities.

11. The electrical assembly of claim 10, wherein the resistivities are equal.

12. The electrical assembly of claim 1, wherein the component includes a first movable electrical contact that electrically connects the component with the first conductor, and a second movable contact that electrically connects the component with the second conductor.

13. The electrical assembly of claim 1, wherein the electrical characteristic includes an impedance; and
the impedance has a first value when the component is connected to the conductor and the additional conductor in a first direction, and a second value that is different from the first value when the component is connected to the conductor and the additional conductor in a second direction.

14. The electrical assembly of claim 13, wherein the identifier includes a resistor and a diode connected in series.

15. The electrical assembly of claim 14, wherein the identifier includes a second resistor in parallel with the resistor and the diode.

16. The electrical assembly of claim 1, wherein the identifier includes a Zener diode.

17. The electrical assembly of claim 1, wherein the identifier includes an identifier controller and a variable resistor; and
the identifier controller adjusts a resistance of the variable resistor according to a component electrical characteristic provided by the component to across the conductor and the additional conductor; and
the electrical characteristic of the identifier includes the resistance.

18. The electrical assembly of claim 17, wherein the component includes a component controller configured to control the component electrical characteristic provided by the component.

19. The electrical assembly of claim 1, wherein the component includes a component controller configured to determine a position of the component relative to the track assembly according to the electrical characteristic and a resistivity of the first conductor.

20. The electrical assembly of claim 1, wherein the conductor includes a first track of the track assembly; and
the additional conductor includes a second track of the track assembly.
